(19) United States
(12) Patent Application Publication
(10) Pub. No.: US 2005/0189653 A1
(43) Pub. Date: Sep. 1, 2005

(54) Dual damascene intermediate structure and method of fabricating same

(76) Inventors: Hun-Jan Tao, Hsin-Chu (TW); Chao-Cheng Chen, Shin-Chu County (TW)

Correspondence Address: SLATER & MATSIL, L.L.P., 17950 PRESTON ROAD, SUITE 1000, DALLAS, TX, 75252, US

(21) Appl. No.: 10/872,946

(22) Filed: Jun. 21, 2004

Related U.S. Application Data
(60) Provisional application No. 60/547,986, filed on Feb. 26, 2004.

(51) Int. Cl. H01L 23/48; H01L 29/40

(52) U.S. Cl. 257/758; 257/774

(57) ABSTRACT

An intermediate structure from which a dual damascene structure may be fabricated includes a first-formed, unfaceted via hole and an intersecting trench both formed by gas plasma etching of a dielectric layer. The sidewall of the via hole is maintained unfaceted during and after trench formation by substantially filling it with a gas-plasma-etchable plug prior to trench formation. The presence of the plug in the via hole during gas plasma etching of the trench, also produces a trench bottom that is substantially flat.

This application claims priority to provisional patent application Ser. No. 60/547,986, entitled “Dual Damascene Intermediate Structure and Method of Fabricating Same,” filed Feb. 26, 2004, which application is incorporated herein by reference.

### TECHNICAL FIELD

The present invention relates to a dual damascene intermediate structure and to methods related thereto. More particularly, the present invention relates to a novel dual damascene intermediate structure, to a method of fabricating the intermediate structure, and to a method of fabricating an improved dual damascene structure therefrom.

### BACKGROUND

The semiconductor industry is engaged in continual attempts to realize improvements in integrated circuits (“ICs”). Some of these improvements are technology-related and include increasing the number of devices on and in a substrate, shrinking the size of the devices and increasing the frequency of on-substrate clocks. Some improvements are customer-related, including decreasing integrated circuit costs and increasing the number of features and functions of ICs.

An International Technology Roadmap for Semiconductors (“ITRS”) has been developed. ITRS represents an industry-wide consensus of present and future R&D that should be conducted to aid in achieving the foregoing improvements. Among the inclusions in ITRS are descriptions of various “technology nodes,” that is, the ground rules for processes governed by the smallest feature that can be fabricated. Previously, the industry has achieved the 160 nm (0.16 micron) node and is aiming to implement the 90 nm (0.09 micron) node sometime in 2004.

The numerical value of a technology node is a measure of (a) the width of interconnect lines on the first level of a multi-level integrated circuit required for economical IC size and/or (b) the gate length of a transistor required for maximum performance. In the case of MOSFETs, this smallest feature is generally taken as the length of a channel defined between a source and a drain. The channel length is substantially the same as the length of a gate between the source and drain. A MOSFET implemented in the 90 nm node will have trenches for horizontal conductors parallel to the substrate and vias for vertical conductors through the levels of a multi-level IC with widths or diameters of 120 nm or less.

Another evolving feature of typical ICs is the trend toward a larger number of metallization layers. Devices with seven, eight, and more metallization layers or metal patterns are not uncommon. Each of the metal layers must be electrically isolated from the underlying and overlying metal layers. For so-called dual damascene processes, in which metal trenches and vias are formed in multi-layer, inter-metal dielectric layers (“IMD,” sometimes also referred to as an inter-level dielectric or “ILD”), an etch stop is typically formed between the layers of the IMD. The characteristics of the etch stop layer causes it to undesirably increase the K or permittivity of the dielectric. Developments relating to dual damascene MOSFETs have led to the use of IMD dielectrics that do not include an etch stop layer sandwiched between layers of dielectric material, as shown in commonly assigned U.S. Pat. No. 6,573,187 (“'187 patent”).

In fabricating a multilevel IC having MOSFETs without following the teachings of the '187 patent, small via holes are etched through the dielectric layers. A larger, upper trench contiguous with each via hole is then etched into the dielectric. When the via hole and trench are filled with an electrically conductive material, the material in the via hole (a “via”) electrically connects a conductive pattern on a lower level of the IC with the conductive material in the trench (a “conductor”), the latter being, in turn, electrically continuous with various items formed on a higher level of the IC. The via hole is formed by using a suitable etching procedure that selectively etches through the dielectric layers and the intervening etch stop layer down to a temporary protective cover on the conductive pattern on the lower level. The trench is then formed in the upper dielectric layer by using a suitable etching procedure that selectively removes material from the upper dielectric layer but is prevented from removing the lower dielectric layer by the etch stop layer.

The '187 patent teaches generally that use of the etch stop layer may be avoided and the low K of the dielectric unaffected—by forming the dielectric layer from two different dielectric materials. For some etchants, the etch rate of the lower dielectric layer is much lower than that of the upper dielectric layer; for other etchants the etch rates are substantially the same. The smaller diameter via is formed by using an etching procedure that selectively etches both dielectric layers at about the same rate. The larger diameter trench is then formed using an etching procedure that selectively etches the upper dielectric layer at a high rate while etching the lower dielectric layer at a very slow rate.

Whether or not the via holes and trenches are formed by the techniques of the '187 patent, it is desirable that each microscopic via hole and trench have vertical or nearly vertical walls and that the bottom of the trench, which intersects the via hole, be substantially horizontal, i.e., generally perpendicular to the via hole and trench walls. These geometric characteristics are particularly advantageous to the fabrication of ICs at the 90 nm node and below. It has been found that via hole and trench formation, as described above, often results in faceting, that is, a via hole with a highly sloped and non-vertical sidewall. Faceting has been found to lead to undesirable IC structure and performance.

As generally depicted in FIGS. 1 and 2a-2d, a known integrated circuit assemblage 8 includes a silicon substrate 9 in and on which are fabricated one or more devices 10, only one of which, such as a FET, is generally depicted. The FET 10 resides at a lower level of the assemblage 8. The free surfaces of the assemblage, including the substrate 9 and the device 10, are covered by an insulative layer 11, for example a low-k inter-metallic, or inter-layer, dielectric (“IMD” or “ILD”). A metal plug 12, typically tungsten, is formed in a hole 13 in the IMD 11 and is connected to an element of the of the device 10, such as its gate electrode or contacts to its source and drain (none are shown).

The free surface of the IMD 11 is covered with a lower etch stop layer 14 and a low-K IMD 15. A copper conductor 16 resides in a trench 17 formed through the IMD 15 and the stop layer 14. Pursuant to damascene protocols, after the trench 17 is formed it is overfilled with copper; chemical-mechanical polishing (“CMP”) or a functionally similar procedure is then employed to “planarize”—remove excess copper from—the IMD 11 and copper above the trench 17 to render the free surfaces of the conductor 16 and the IMD 15 coplanar.

A damascene structure 18 at a next higher level above the assemblage 8 resides above the IMD 15 and the conductor 16. The structure 18 includes, in order from lowest to highest, an etch stop layer 19, a first insulative, dielectric layer 20 and a second insulative, dielectric layer 21. The insulative layers 20 and 21, which are low-k dielectrics, may be the same or different materials and may be separated by an optional etch stop layer 22, if the teachings of the '187 patent are not utilized. For this reason, in the claims hereof, the phrase “dielectric layer” is used to jointly refer to the layers 20 and 21.

A via hole 23 passes through the layers 19 and 20, and intersects the bottom or floor of a conductor trench 24 in the layer 21. The floor of the trench 24 is typically the upper surface of the IMD 11. The via hole 23 and the trench 24 are filled with copper, which comprises a continuous via 26 and conductor 27. The conductor 27 and the device 10 are electrically continuous through a path 26-16-13. The damascene structure 18 may be repeated upwardly as often as necessary to complete a multi-level dual damascene integrated circuit.

As shown in FIGS. 2a-2d, the structure 18 may be fabricated pursuant to a “via first” procedure in which the via hole 23 is formed prior to the trench 24. More specifically, after the conductor 16 and the layer 15 are planarized, the etch stop layer 19 and the dielectric layers 20 and 21, with or without the etch stop layer 22, are deposited, FIG. 2a.

A resist or mask layer 30 is deposited as a continuous layer on the free surface of the dielectric layer 21 and is patterned, relative to the conductor 16 (FIG. 2b), to define an opening 32 that is congruent with and overlies the incipient via hole 23, that is, the opening 32 is in vertical alignment with the conductor 16. The via hole 23 is formed, as by gas plasma (or dry) etching, into and through the dielectric layers 20,21 (and the stop layer 22, if used) through the opening 32. Etching of the conductor 16 is prevented by the stop layer 19. After the resist or mask 30 is removed, another resist or mask 34 is deposited on the dielectric layer 21 and is patterned to define an opening 36 having the size and location of the trench 24 (FIG. 2c). The trench 24 is formed by gas plasma etching through the layer 21. The stop layer 22, or differences between the etchability of the materials of the layers 20 and 21, prevents etching of the layer 20. Etching through the opening 36 produces a juncture 38 of the viahole 23 and the trench 22 (FIG. 2d). The juncture 38 is the bottom of the trench 24, which is generally centrally pierced or intersected by the via hole 23 so that the two are contiguous.

Subsequently, the via hole 23 and the trench 24 are filled with a conductive material such as copper to form a continuous via-conductor 26-27, which, at the bottom of the via 26, contacts the conductor 16 from which the stop layer 19 has been removed. The conductor 16, and any item, such as the device 10, with which it is electrically continuous at the lower level of the assemblage 8 may ultimately be rendered electrically continuous with an item to which the conductor 27 is electrically continuous at a higher level.

As illustrated in FIGS. 2d and 3, filling the via hole 23 and the trench 24 with copper may be achieved by first vapor- or sputter-depositing a continuous barrier layer 50 on the sidewalls of the via hole 23 and the trench 24 and on the top of the dielectric layer 21 (if the resist 34 has been previously removed) to protect the dielectric layer 21 from the effects of subsequent metal deposition steps. The barrier layer 50 may be tantalum, tantalum nitride or other suitable material. Next, a continuous seed layer 52 of copper is deposited on the barrier layer 50. Thereafter, copper is deposited by electrochemical deposition (“ECD”) and built up on the seed layer 52, ultimately filling the via hole 23 (to form the via 26) and the trench 24 (to form the conductor 27), and depositing the copper on the free surface of the dielectric layer 21. Subsequently, the structure 18 is planarized by chemical-mechanical polishing (“CMP”) or a functionally equivalent process to render the conductor 27 and the free surface of the dielectric layer 21 coplanar at a selected level 60, resulting in the structure 18 shown in FIG. 1.

It is important to note that FIGS. 1 and 2d depict an idealized structure 18, which differs from the structure 18 that typically actually results from the foregoing prior art procedures. Specifically, as shown in FIG. 3, it has been found that, when the above-described conventional prior art techniques are used to produce a dual damascene structure 18, the via hole 23 and the via 26, as they exist in the structure 18 of FIGS. 1 and 2d, usually do not have vertical or nearly vertical side walls, and are slanted or highly faceted. That is, the area of the bottom of the trench 24, the juncture 38 between the via hole 23 and the trench 24, is decreased because of the upwardly expanding conical profile assumed by the slanted sidewall of the via hole 23, as illustrated at 62 in FIG. 3. The faceting 62 depicted in FIG. 3 is exaggerated for purposes of illustration. The faceting 62 may not be as extreme as depicted in FIG. 3 and may not extend throughout the depth of the via hole 23. The severity of the faceting 62 varies with the materials and processes utilized to produce the via hole 23 and the trench 24. The faceting is caused by unintended gas plasma etching of the via hole 23 during the intended gas plasma etching of the trench 24. The faceted profile 62, exemplified by the slanted sidewall of the via hole 23, is undesirable.

Specifically, it appears that the presence of the large amount of copper necessarily present in the trench 24, coupled with the presence of the undesirably large amount of copper in the enlarged or faceted via hole 23, lead to the free surface of the copper in the trench 24 becoming dished or concave by CMP procedures. Dishing is known to lead to copper residue being present in and on the dielectric layer 21 at the edge of the copper at the top of the trench 24, resulting in diffusion of copper ions into the layer 21, thereby compromising its dielectric properties. Further, near the bottom of the faceted via 26 there is present a greater thickness of the barrier layer 50 and the seed layer 52, as well as a larger mass of the copper, than would be the case if the sidewall of the via hole 23 was substantially vertical and unfaceted. These large amounts of conductive materials have a deleterious effect on the desirably low capacitance between the copper of the via 26 and metal or conductive items elsewhere in the structures 8 and 18. If the via hole 23 is made to be less high or to have a smaller diameter in order to decrease the amount of barrier and seed layer material 50 and 52 and copper therein, expedient formation of the via 26 precisely in the desired location is rendered difficult.

Thus, elimination of the faceting or slanting 62 of the sidewall of the via hole 23 is a key to the expedient fabrication of reliable dual damascene structures 18 at 90 nm or less.

### SUMMARY OF THE INVENTION

The present invention contemplates an intermediate dual damascene structure and methods related thereto.

In its device aspects, the present invention contemplates an intermediate dual damascene structure usable for the fabrication of a dual damascene structure. The intermediate structure includes a dielectric. The dielectric has a via hole that is gas plasma etched therethrough. The via hole sidewall is generally unfaceted and normal to the dielectric layer.

The via hole is substantially filled with a plug. The plug comprises a material that is selected to possess the following two properties: (1) The material has a substantially the same gas plasma etch rate (e.g., ±15%) as the dielectric layer, and (2) The material is capable of filling small spaces, such as the micro- and nano-spaces present in an integrated circuit. As a trench is gas plasma etched into the dielectric so as to intersect the via hole, the plug is also etched, but it continues to substantially fill the via hole. As a result, following gas plasma etching of the trench, the essentially unetched sidewall of the via hole remains substantially vertical and unfaceted; the profile of the trench's bottom, i.e., the junction between the via hole and the trench, is substantially horizontal.

In its method aspects, the present invention contemplates a method of making the above-described intermediate structure and a method of making a damascene structure from the intermediate structure.

### BRIEF DESCRIPTION OF THE DRAWINGS

FIG. 1 is a generalized, idealized, sectioned view of a dual damascene intermediate structure according to the prior art.

FIGS. 2a-2e are idealized schematic depictions illustrating a prior art method of producing the intermediate structure of FIG. 1.

FIG. 3 is a magnified sectioned view of the profile of a via and an intersecting trench as that profile exists in reality in the structures shown in FIGS. 1 and 2a-2e, the view illustrating the undesirable via faceting and sidewall non-verticality which may occur in a prior art damascene structure of the type shown in FIG. 1 when the prior art procedures of FIGS. 2a-2e are employed.

FIG. 4 is a generalized, sectioned view of a dual damascene intermediate structure fabricated in accordance with the principles of the present invention as an improvement of and a replacement for the intermediate structure of the prior art depicted in FIGS. 1-3.

FIGS. 5a-5c illustrate a method of using the intermediate structure of FIG. 4 to form a via hole and an intersecting trench having a non-faceted, mildly terraced or mildly concave profile at the juncture of the via hole and the trench.

FIG. 6 is a magnified, sectioned view of a mildly terraced via-conductor profile produced by the method of FIGS. 5a-5c using the intermediate structure of FIG. 4.

FIG. 7 is a illustrates a mildly concave via-conductor profile produced by the method of FIGS. 5a-5c using the structure of FIG. 4.

### DETAILED DESCRIPTION OF ILLUSTRATIVE EMBODIMENTS

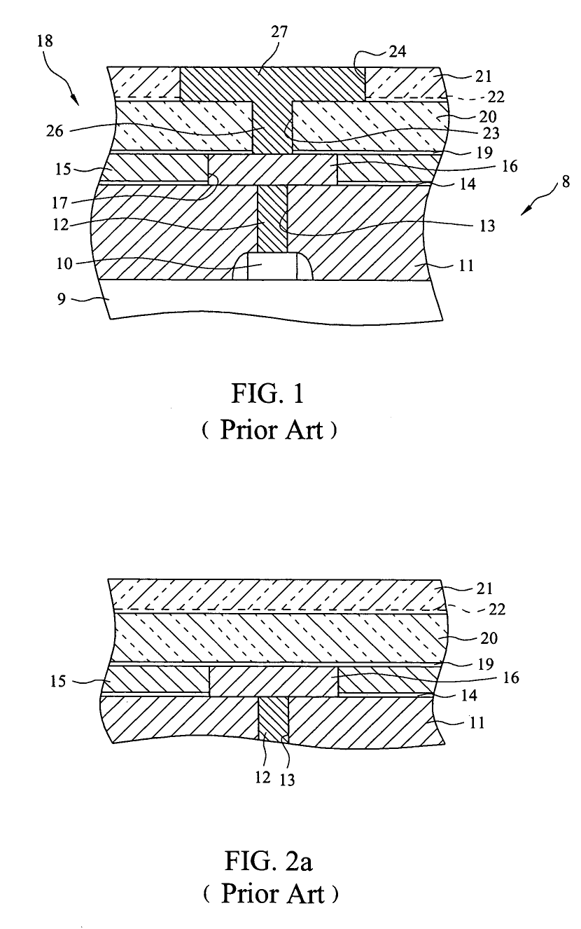

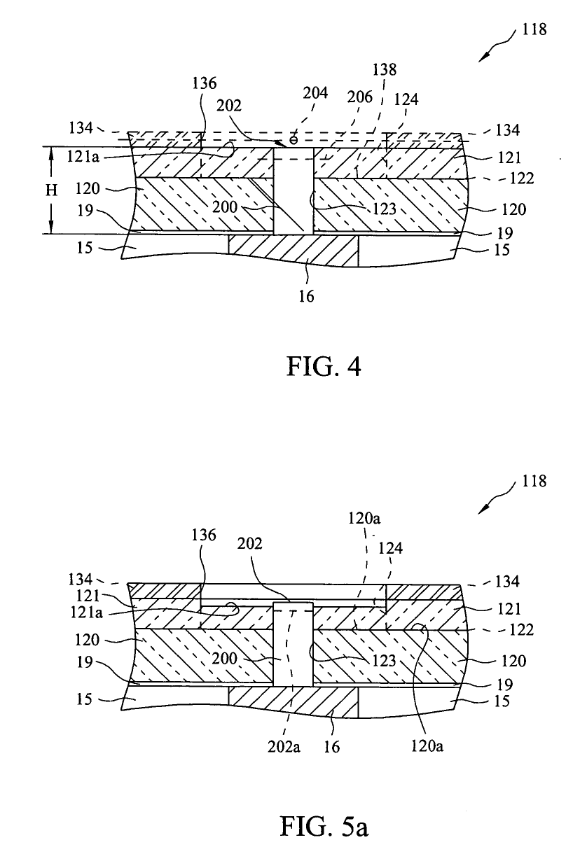

The prior art has been described above with reference to FIGS. 1-3. The present invention is described with reference to FIGS. 4-7, elements depicted therein being designated by reference numerals which are the same as or similar to the reference numerals used in FIGS. 1-3.

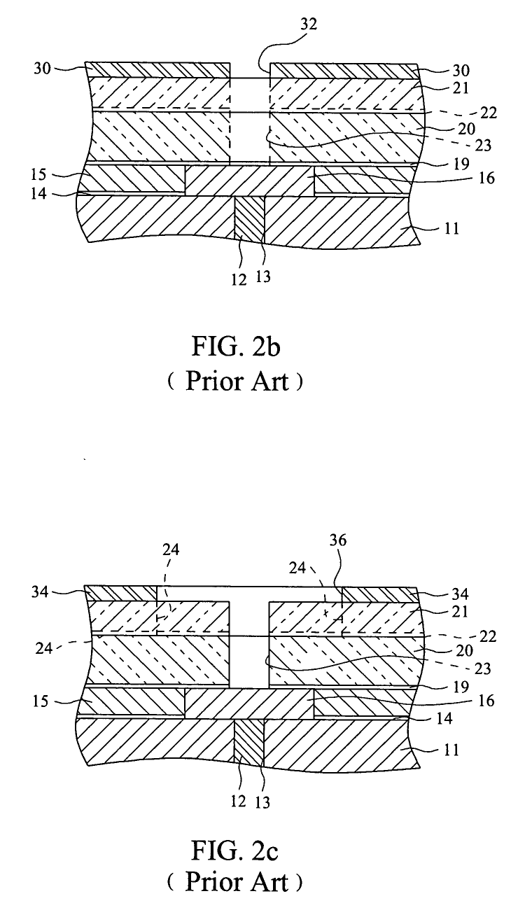

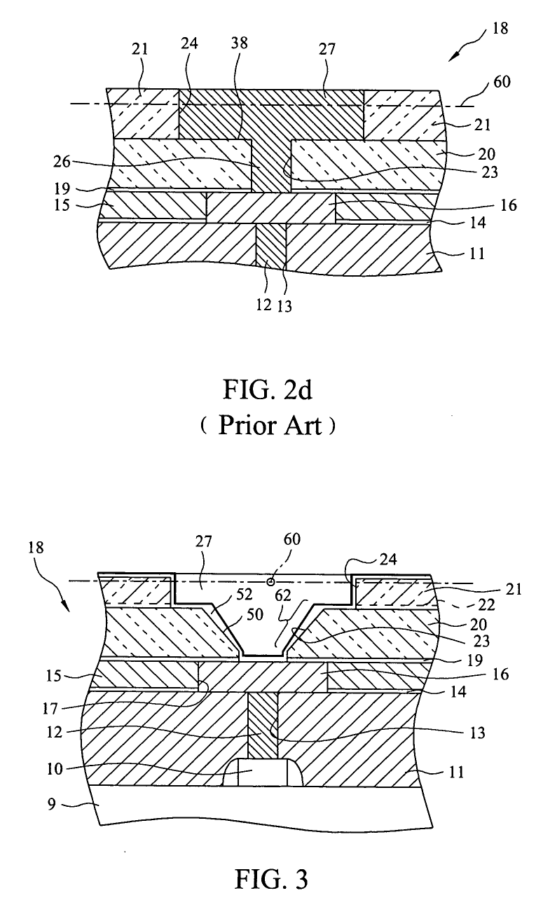

FIG. 4 depicts an intermediate dual damascene structure 118 according to the present invention. This intermediate structure 118 is an improvement of the in-process structure 18 of the prior art as such exists after formation of the via hole 123 (23 in FIGS. 2c and 3) and before the etching of the trench 124 (24 in FIGS. 2d and 3).

Prior to the formation of the trench 124, a plug 200 is deposited or otherwise placed in the via hole 123 formed through the stop layer 19 and the dielectric layers 120 and 121. In preferred embodiments, the material of the layer 121 is selected as a gas-plasma-etchable material, such as an oxide, e.g., silicon oxide; a fluorine-doped silicon glass (“FSG”), e.g., SiO₂ doped with fluorine; or a carbon-doped oxide. The plug 200 preferably comprises a gas-plasma-etchable material capable of filling small spaces or gaps, such as an organic material (e.g., a bottom anti-reflection coating or “BARC;” a photoresist, including an I-line resist or a deep UV resist; or a resin) or a SiC-containing material. Other materials that function in accordance with the principles hereof as described below may also be used.

The plug 200 may overfill, underfill or substantially fill the via hole 123. However, designating as H the height above the IMD 15 of the free surface of the layer 121, the distance of the top, or upper free surface, 202 of the plug 200 above the IMD 15 is equal to H±15%, as indicated by the dashed lines 204 and 206. Accordingly, the phrase “substantially fill” means herein H±15%. Moreover, the materials of the plug 200 and the layer 121, as well as gas plasma etch variables (etchant gas, pressure, time, and temperature) are all selected so that as the plug 200 and the layer 121 are gas plasma etched to form the trench 124, the receding or decreasing top-to-layer 202-to-15 distance continues to be equal to the decreasing value of the receding H±15%. That is, during gas plasma etching, the plug 200 continues to substantially fill the via hole 123. Suitable gases for gas plasma etching of the layer 121 and the plug 200 include compounds containing a halogen, such as C_{X}F_{Y}H_{Z} alone or mixed with O₂ and/or N₂ and/or an inert gas.

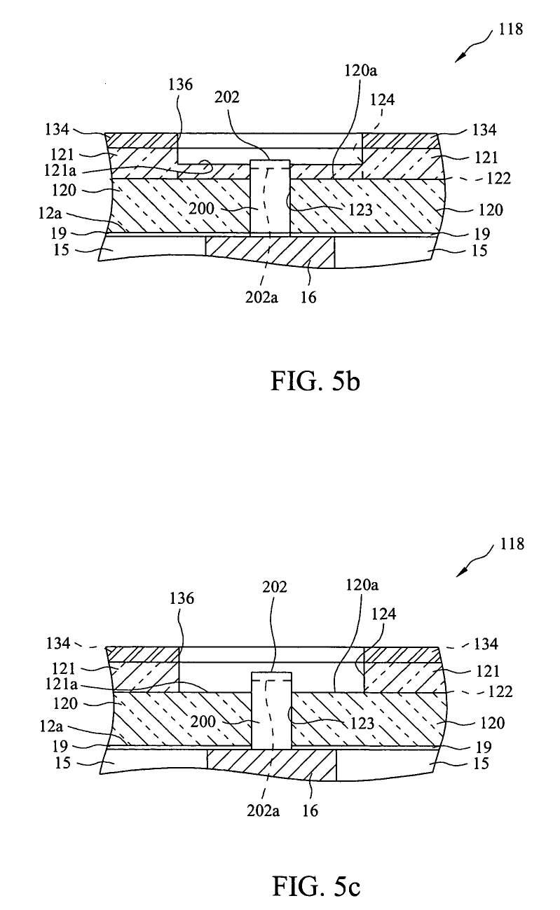

FIGS. 4 and 5a illustrate a method according to the present invention, wherein the top 202 of the plug 200 and the free surface 121a of the layer 121 are approximately coplanar before plasma etching is initiated (FIG. 4), while the top 202 is about 5% farther from the IMD 15 than the surface 121a—which is also the bottom of the deepening trench 124—shortly after plasma etching begins (FIG. 5a). In FIG. 5b, plasma etching has proceeded, and the receding top 202 is now about 11% farther from the IMD 19 than is the receding surface 121a of the layer 121. In FIG. 5c, as the receding surface 121a of the layer 121 reaches, and “merges” with, the upper surface 120a of the layer 120, its distance from the IMD 19 is about 14% less than that of the top 202. Etching of the layer 120 does not occur, because of either the different compositions of the layers 120 and 121 or the presence of the stop layer 122. A broken line 202a in FIGS. 5a-5c also illustrates the concurrent receding movement of the top 202 and the surface of the layer 121, when the top 202 of the plug 200 is initially, and remains, below the surface 121a but remains within ±15% of H.

Ultimately, when etching of the trench 124 is completed, the remainder of the plug 200 is removed and the via hole 123 and the trench 124 are filled with copper by conventional barrier/seed techniques, as described earlier regarding FIG. 3, followed by CMP or other planarization as in FIG. 2d.

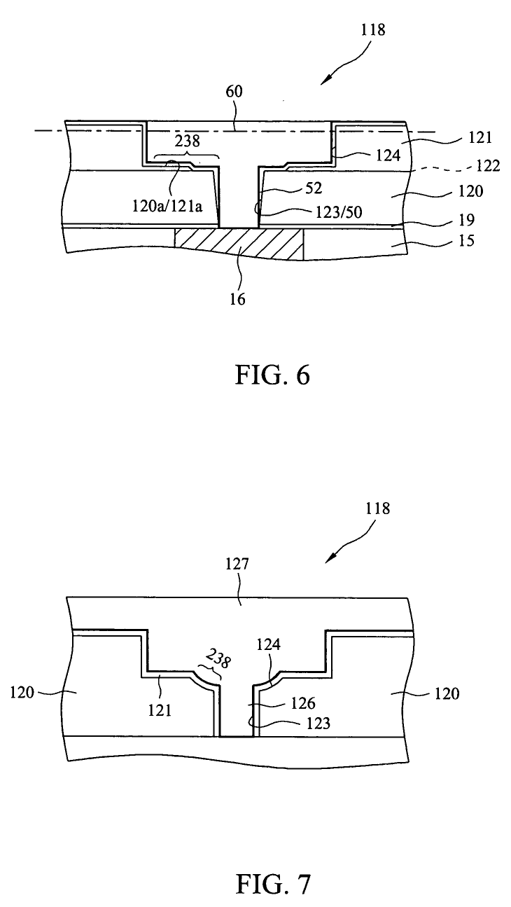

As shown in FIG. 6, appropriate selection of the materials of the plug 200, the layer 121 and gas plasma etch variables result in the side wall of the via hole 123 being essentially vertical and non-faceted and the bottom 120a/121a of the trench 124 essentially horizontal. The presence of the plug 200 may result in a mild terracing, indicated at 238 in FIG. 6, of the substantially horizontal trench bottom 120a/121a between the via hole 123 and the trench 122. This terracing 238, which may comprise a mildly concave, two-step profile, as shown in FIG. 7, is thought to be caused by “reflection” or rebounding of the gas plasma from the side of the plug 200 when the top 202 thereof remains above the “moving” trench bottom 121a as etching of the trench 124 proceeds. Such rebounding slightly enhances etching of the trench bottom 121a proximate to the plug 200.

Thus, a preferred method of producing an intermediate structure according to the present invention comprises, in sequence, FIGS. 2a, 2b and 4. A preferred method of producing a damascene structure comprises, in sequence, FIGS. 2a, 2b, 4, 5a-5c, and 6.

Following removal of the plug 200, the via hole 123 and the trench 124 are filled with copper or other suitable conductive material, as described above. The improved structure 118 is then subjected to CMP or an equivalent process. It has been found that, following CMP, much less residue of the copper is present in the dielectric layer 121 adjacent the edge of the copper-filled trench 124. The occurrence of this desideratum is ascribed to there being less dishing of the copper effected by CMP. Less dishing, in turn, is due to there being no large mass of copper below the copper in the trench 124. Moreover, since the lack of faceting of the trench 123 and of the copper therein results in there being a smaller amount of copper near the bottom of the smaller volume via hole 123, the inter-metal capacitance exhibited by the intermediate structure 118 is less than that possessed by intermediate structures 18 exhibiting the faceting 62 of the via hole 23 as in FIG. 3.

The fabrication of the dual damascene structure 118 (and of the lower assemblage 8) then proceeds in a conventional manner, except that, preferably, subsequent via holes and vias, and trenches and conductors, in levels above the structure 118 are formed according to the present invention.

Particular embodiments of the invention are described herein. It is to be understood that the invention is not limited in scope by the description and includes those modifications and equivalents covered by the following claims hereof as would be apparent to those having ordinary skill in the field of this invention. Specifically, various changes, substitutions and alterations can be made herein without departing from the spirit and scope of the invention as defined by the appended claims. The scope of the present application is not intended to be limited to the particular embodiments of the intermediate structure and method described herein. As one of ordinary skill in the art will readily appreciate from the foregoing disclosure, intermediate structures and methods of making them that presently exist or are later developed and that perform substantially the same function or achieve substantially the same result as the corresponding embodiments described herein may be utilized according to the present invention. The appended claims are intended to include within their scope such structures and methods.

1. An intermediate structure from which a dual damascene structure may be fabricated, comprising:
a dielectric layer on an integrated circuit assemblage, the dielectric layer having a via hole formed therethrough, the via hole being aligned with a selected area of the assemblage and having a substantially unfaceted sidewall that is substantially normal to the free surface of the dielectric layer, and a trench formed partially therein that intersects the via hole, the bottom of the trench being a surface that is substantially parallel to the free surface of the dielectric layer and substantially normal to the via hole sidewall.

2. An intermediate structure as in claim 1 wherein the bottom surface of the trench nearer to the intersection of the via hole and the trench is slightly lower than the bottom surface of the trench farther from the intersection.

3. An intermediate structure as in claim 1 wherein the bottom surface of the trench is mildly terraced.

4. An intermediate structure as in claim 1 wherein the bottom of the trench is mildly concave.

5. An intermediate structure as in claim 1 further comprising a conductive material filling the trench and the via hole.

6. An intermediate structure from which a dual damascene structure may be fabricated, comprising:
a gas-plasma-etchable dielectric layer on an integrated circuit assemblage, the dielectric layer having a via hole formed therethrough, the via hole being aligned with a selected area of the assemblage and having a substantially unfaceted sidewall that is substantially normal to the free surface of the dielectric layer; and
a gas-plasma-etchable plug substantially filling the via hole, the gas etch rate of the plug being substantially equal to the gas etch rate of the dielectric layer.

7. An intermediate structure as in claim 6 wherein the gas etch rates of the plug and the dielectric layer are within ±15% of each other.

8. An intermediate structure as in claim 7 wherein the plug is composed of an organic material or an SiC-containing material.

9. An intermediate structure as in claim 8 wherein the material of the plug is capable of filling small spaces.

10. An intermediate structure as in claim 9 wherein the organic material comprises a BARC, a resin or a photoresist.

11. An intermediate structure as in claim 7 wherein the dielectric layer is an oxide, an FSG or a carbon-doped oxide.

12. An intermediate structure as in claim 10 wherein the dielectric layer comprises an oxide, an FSG or a carbon-doped oxide.

13. An intermediate structure as in claim 12 wherein the plug and the dielectric layer are gas-plasma-etchable by a halogen-containing compound.

14. An intermediate structure as in claim 14 wherein the halogen-containing compound is C_{X}F_{Y}H_{Z} alone or mixed with O₂, N₂, an inert gas or a combination thereof.

15. An intermediate structure from which a dual damascene structure may be fabricated, comprising:
a dielectric layer on an integrated circuit assemblage, the dielectric layer being gas-plasma-etchable by a halogen-containing compound and having a via hole formed therethrough, the via hole being aligned with a selected area of the assemblage and having a substantially unfaceted sidewall that is substantially normal to the free surface of the dielectric layer; and
a plug filling the via hole, the plug being composed of an organic material or an SiC-containing material capable of filling small spaces and being gas-plasma-etchable by the halogen-containing compound, the etch rates of the plug and the dielectric layer being within ±15% of each other.

16. An intermediate structure as in of claim 15, wherein:
the organic material comprises a BARC, a resin or a photoresist;
the dielectric layer comprises an oxide, an FSG or a carbon-doped oxide; and
the halogen-containing compound comprises C_{X}F_{Y}H_{Z} alone or mixed with O₂, N₂, an inert gas or a combination thereof.

17. A method of making an intermediate structure from which a dual damascene structure may be fabricated, which comprises:
forming a via hole through a gas-plasma-etchable dielectric layer on an integrated circuit assemblage, the via hole being aligned with a selected area of the assemblage and having a substantially unfaceted sidewall that is substantially normal to the free surface of the dielectric layer; and
substantially filling the via hole with a plug composed of a gas-plasma-etchable material having an etch rate within ±15% of the etch rate of the dielectric layer.

18. An intermediate structure made by the method of claim 17.

19. A method as in claim 17, further comprising forming a via hole-intersecting trench in the dielectric layer by subjecting the dielectric layer and the plug to gas etching, so that, as the trench is formed, the wall of the via hole remains substantially unfaceted.

20. An intermediate structure made by the method of claim 19.

21. A method as in claim 19, further comprising removing the plug from the via hole after the trench is formed.

22. An intermediate structure made by the method of claim 21.

23. A method of making a damascene structure from the structure of claim 22, further comprising depositing an electrically conductive material in, and filling, the via hole and the trench.

24. An damascene structure made by the method of claim 23.

25. A method as in claim 23, further comprising planarizing the structure after the depositing step.

26. An intermediate structure made by the method of claim 25.

27. A method as in claim 17 further comprising forming a via hole-intersecting trench in the dielectric layer by subjecting the dielectric layer and the plug to gas plasma etching, so that, as the trench is formed the via hole remains substantially unfaceted and the bottom of the trench is substantially flat and normal to the via hole sidewall.

28. A method as in claim 27 wherein the bottom of the trench nearer the via hole-trench intersection is slightly lower that the trench bottom farther from the intersection.

29. A method as in claim 27 wherein the bottom of the trench is mildly terraced.

30. A method as in claim 27 wherein the bottom of the trench is mildly concave.

31. A method as in claim 27, further comprising removing the plug from the via hole after the trench is formed.

32. A method of making a damascene structure comprising the method of 31 and further comprising depositing an electrically conductive material in, and filling, the via hole and the trench.

33. A method as in claim 32, further comprising planarizing the structure after the depositing step.

34. A method as in claim 17 wherein the plug is composed of an organic material or an SiC-containing material.

35. A method as in claim 34 wherein the material of the plug is capable of filling small spaces.

36. A method as in claim 35 wherein the organic material is a BARC material, a resin or a photoresist.

37. A method as in claim 35 wherein the dielectric layer comprises an oxide, an FSG or a carbon-doped oxide.

38. A method as in claim 36 wherein the dielectric layer is an oxide, an FSG or a carbon-doped oxide.

39. A method as in claim 38 wherein the plug and the dielectric layer are gas-plasma-etchable by a halogen-containing compound.

40. A method as in claim 39 wherein the halogen-containing compound is C_{X}F_{Y}H_{Z} alone or mixed with O₂, N₂, an inert gas or a combination thereof.
